(19) United States
(12) Patent Application Publication
(10) Pub. No.: US 2025/0338555 A1
(43) Pub. Date: Oct. 30, 2025

(54) GATE CONTACT FORMATION WITH SOURCE/DRAIN CONTACT ISOLATION

(71) Applicant: INTERNATIONAL BUSINESS MACHINES CORPORATION, ARMONK, NY (US)

(72) Inventors: Genevieve Beique, Latham, NY (US); Tao Li, Slingerlands, NY (US); Ruilong Xie, Niskayuna, NY (US); Julien Frougier, Albany, NY (US)

(21) Appl. No.: 18/649,488

(22) Filed: Apr. 29, 2024

(51) Int. Cl. H01L 29/417; H01L 21/8234; H01L 23/535; H01L 27/088; H01L 29/06; H01L 29/40; H01L 29/423; H01L 29/66; H01L 29/775

(52) U.S. Cl. CPC H10D 30/6729; H01L 23/535; H10D 30/014; H10D 30/43; H10D 30/6735; H10D 62/121; H10D 64/01; H10D 84/013; H10D 84/0149; H10D 84/0151; H10D 84/038; H10D 84/83

(57) ABSTRACT

Embodiments of present invention provide a semiconductor structure. The semiconductor structure includes a dielectric contact cut between a first source/drain contact of a first transistor and a second source/drain contact of a second transistor; a gate structure shared by the first and the second transistor; and a gate cap on top of the gate structure, where a top surface of the dielectric contact cut is substantially coplanar with a top surface of the gate cap and substantially coplanar with top surfaces of the first S/D contact and the second S/D contact. A method of forming the same is also provided.

### BACKGROUND

The present application relates to manufacturing of semiconductor integrated circuits. More particularly, it relates to method of forming gate contact with source/drain contact isolation and the structure formed thereby.

As semiconductor industry moves towards smaller node, transistors such as field-effect-transistors (FETs) are aggressively scaled to fit into reduced footprint or real estate, dictated by the node size, for increased device density.

In association with the continuous scaling of semiconductor devices, issues such as tight tip-to-tip distance between metal contacts, such as source/drain contacts, of transistors are addresses. For example, a dielectric contact cut is used to separate two tightly spaced source/drain contacts of two neighboring transistors. However, conventional formation of the dielectric contact cut leaves little or no room for forming gate contact over source/drain region.

### SUMMARY

Embodiments of present invention provide a semiconductor structure. The semiconductor structure includes a dielectric contact cut between a first source/drain (S/D) contact of a first transistor and a second S/D contact of a second transistor; and a dielectric gate cap on top of a gate structure, the first transistor and the second transistor sharing the gate structure, where a top surface of the dielectric contact cut is substantially coplanar with a top surface of the dielectric gate cap, which makes it easier to form a gate contact at an extension or extended direction of the dielectric contact cut.

According to one embodiment, the semiconductor structure further includes a gate contact that is in contact with the gate structure shared by the first and the second transistor, where a lower portion of the gate contact is separated from the dielectric contact cut by a gate spacer.

According to another embodiment, the semiconductor structure further includes a first via in contact with the first S/D contact and a second via in contact with the second S/D contact, where top surfaces of the first via and the second via are coplanar with a top surface of the gate contact.

In one embodiment, the gate contact is positioned in an extension of the dielectric contact cut, the extension being in a direction along a length of the gate structure shared by the first and the second transistor.

In another embodiment, a top surface of the gate contact is above the top surface of the dielectric contact cut.

In yet another embodiment, the top surface of the dielectric contact cut is substantially coplanar with top surfaces of the first and the second S/D contact of the first and the second transistor.

In one embodiment, the dielectric contact cut is horizontally between a first S/D region underneath the first S/D contact of the first transistor and a second S/D region underneath the second S/D contact of the second transistor.

In another embodiment, the dielectric contact cut has a depth that is below a top surface of a first S/D region of the first transistor and below a top surface of a second S/D region of the second transistor.

Embodiments of present invention further provide a method of forming a semiconductor structure. The method includes forming a first transistor having a first source/drain (S/D) region; forming a second transistor having a second S/D region; forming a gate structure shared by the first transistor and the second transistor; forming a dielectric contact cut and a first and a second S/D contact separated by the dielectric contact cut, the first and the second S/D contact contacting, respectively, the first and the second S/D region of the first and the second transistor; and forming a gate contact contacting the gate structure shared by the first and the second transistor, where a lower portion of the gate contact being horizontally separated from the dielectric contact cut by a gate spacer, and a top surface of the gate contact being above a top surface of the dielectric contact cut. By being above the top surface of the dielectric contact cut, the gate contact may be formed in a process without the concern of affecting the dielectric contact cut.

In one embodiment, forming the dielectric contact cut includes creating an opening, in an etch process selective to the gate spacer, in a dielectric layer between the first and the second S/D region and subsequently filling the opening with a first dielectric material to form the dielectric contact cut.

In another embodiment, forming the first and the second S/D contact includes creating a first and a second contact opening, in an etch process selective to the dielectric contact cut, in the dielectric layer with the first and the second contact opening exposing the first and the second S/D region; filling the first and the second contact opening with a first conductive material; and applying a chemical-mechanical-polishing (CMP) process to planarize top surfaces of the first and the second S/D contact, wherein the CMP process exposes a top surface of the dielectric contact cut and a top surface of a gate cap above the gate structure shared by the first and the second transistor.

In yet another embodiment, forming the gate contact includes creating a gate contact opening, in an etch process selective to the gate spacer, in the gate cap exposing a portion of the gate structure shared by the first and the second transistor; and filling the gate contact opening with a second conductive material to form the gate contact.

According to one embodiment, the method further includes depositing a dielectric layer on top of the gate cap and the first and the second S/D contact; and forming in the dielectric layer one or more vias contacting the first and the second S/D contact.

In one embodiment, the gate contact is positioned in an extension of the dielectric contact cut, the extension being in a direction along a length of the gate structure shared by the first and the second transistor.

In another embodiment, the dielectric contact cut extends below top surfaces of the first S/D region and the second S/D region of the first and the second transistor.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C to FIGS. 9A, 9B, and 9C are demonstrative illustrations of cross-sectional views and FIG. 1D to FIG. 9D are simplified top views of a semiconductor structure at various steps of manufacturing thereof according to embodiments of present invention; and

FIG. 10 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

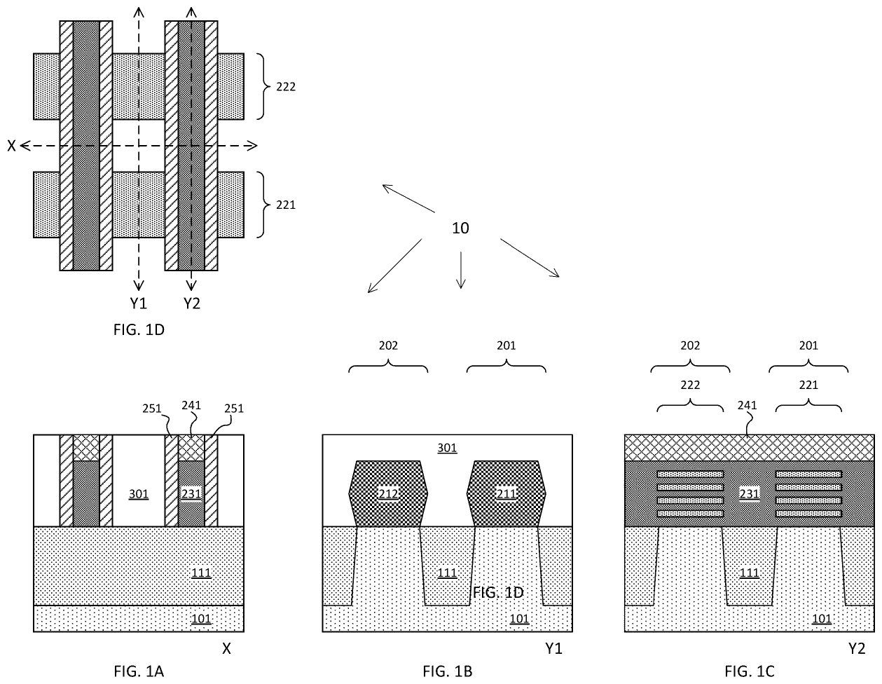

FIGS. 1A, 1B, and 1C are demonstrative illustrations of different cross-sectional views and FIG. 1D is a simplified top view of a semiconductor structure in a step of manufacturing thereof according to one embodiment of present invention. More specifically, FIG. 1A illustrates a cross-sectional view of the semiconductor structure along a dashed line X as illustrated in FIG. 1D. In other words, the cross-sectional view in FIG. 1A is made across the gate in a direction along the length of the gate. FIG. 1B illustrates a cross-sectional view of the semiconductor structure along a dashed line Y1 as illustrated in FIG. 1D. In other words, the cross-sectional view in FIG. 1B is made across the S/D region in a direction along the width of the gate. FIG. 1C illustrates a cross-sectional view of the semiconductor structure along a dashed line Y2 as illustrated in FIG. 1D. In other words, the cross-sectional view in FIG. 1C is made across the gate in a direction along the width of the gate. As its purpose is to show locations of the various cross-sections illustrated in FIGS. 1A, 1B, and 1C, FIG. 1D may only selectively illustrate key elements such as, for example, nanosheets, gates, S/D regions, and elements that are yet to be formed or whose views may be covered. Other elements such as dielectric cap layer, sidewall spacers, etc. may not necessarily be illustrated in order not to overcrowd FIG. 1D, and to the extent that their omission from FIG. 1D does not hinder the description of embodiments of present invention, which are mainly provided hereinafter with reference to FIGS. 1A, 1B, and 1C.

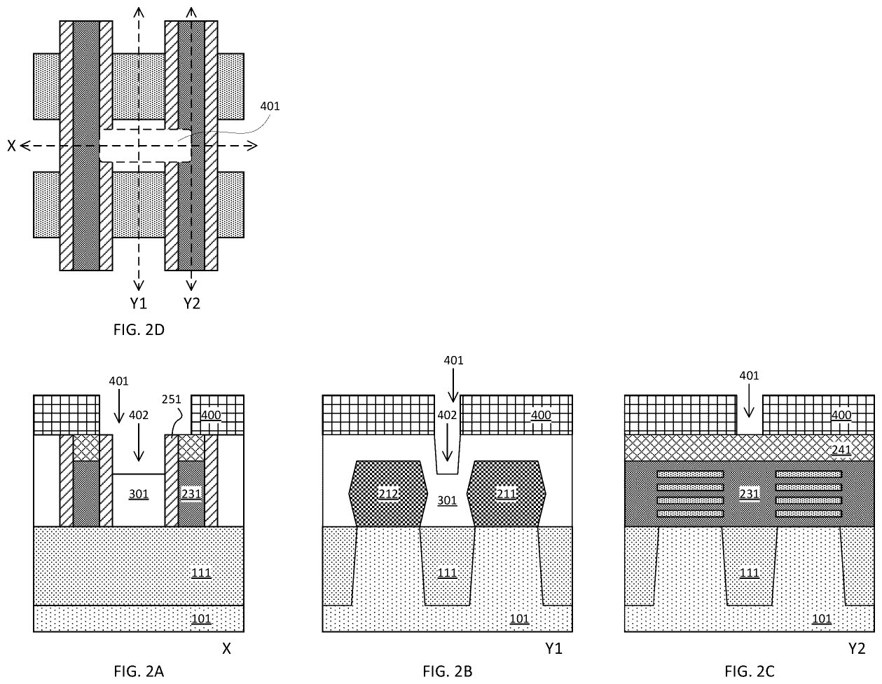

Likewise, FIGS. 2A, 2B, and 2C to FIGS. 9A, 9B, and 9B are demonstrative cross-sectional views and FIG. 2D to FIG. 9D are simplified top views of the semiconductor structure, at different manufacturing steps, illustrated in manners similar to FIGS. 1A, 1B, 1C, and 1D respectively.

Embodiments of present invention provide forming a semiconductor structure 10 that is demonstratively illustrated to include multiple nanosheet transistors, although embodiments of present invention are not limited in this aspect and may be applied to other types of transistors and/or active devices. More particularly, the semiconductor structure 10 may include a semiconductor substrate 101 upon which there may be formed, at least, a first transistor 201 and a second transistor 202. The first transistor 201 may include a first source/drain (S/D) region 211 and the second transistor 202 may include a second S/D region 212. The first and the second transistor 201 and 202 may share a gate structure 231 that may include a first gate of the first transistor 201 and a second gate of the second transistor 202. More specifically, the gate structure 231 may include a layer of gate metal surrounding a first stack of nanosheets 221 of the first transistor 201 and a second stack of nanosheets 222 of the second transistor 202, via a gate dielectric layer and one or more work-function metal layers. The gate dielectric layer may be a layer of high-k dielectric material such as hafnium (Hf)-based dielectrics (e.g., hafnium-oxide, hafnium-silicon-oxide, hafnium-silicon-oxynitride, hafnium-aluminum-oxide, etc.) or other suitable high-k dielectrics (e.g., aluminum-oxide, tantalum-oxide, zirconium-oxide, etc.). The work-function metal layers may include layers of titanium-nitride, titanium-aluminum-carbide, titanium-carbide, titanium-aluminum-oxide, tungsten-nitride, etc. The layer of gate metal may be a layer of conductive material such as, e.g., tungsten, aluminum, copper, cobalt, ruthenium, or other suitable materials. The gate structure 231 shared by the first and the second transistor 201 and 202 may be a metal gate.

The first and the second S/D region 211 and 212 may be covered by a dielectric layer 301, and the shared gate structure 231 may be covered by a gate cap 241, which in one embodiment may be a layer of gate mask. Gate spacers 251 may be formed at sidewalls of the shared gate structure 231 as well as at sidewalls of the gate cap 241 on top of the shared gate structure 231.

In one embodiment, the semiconductor substrate 101 may be, for example, a bulk silicon (Si) substrate, a bulk germanium (Ge) substrate, a silicon-on-insulator (SOI) substrate, or a stack of semiconductor and/or insulator layers. Shallow-trench-isolations (STIs) 111 may be formed in the semiconductor substrate 101 in areas between the first and the second transistor 201 and 202.

FIGS. 2A, 2B, and 2C are demonstrative illustrations of different cross-sectional views and FIG. 2D is a simplified top view of a semiconductor structure in a step of manufacturing thereof according to one embodiment of present invention. More particularly, following the step illustrated in FIGS. 1A-1D, embodiments of present invention provide forming a mask 400 (soft mask or hard mask) by depositing, for example, an organic planarization (OPL) layer on top of the gate cap 241 and gate spacers 251 of the first and the second transistor 201 and 202, and on top of the dielectric layer 301 surrounding the first and the second transistor 201 and 202. The OPL layer may subsequently be patterned, for example through a lithographic patterning and etch process to form the mask 400. The mask 400 has, for example, an opening 401 that exposes a portion of the dielectric layer 301 that is between the first and the second S/D region 211 and 212 of the first and the second transistor 201 and 202.

After forming the mask 400, embodiments of present invention provide etching the exposed portion of the dielectric layer 301, in an etch process that is selective to both the gate cap 241 and the gate spacers 251. Thereby, the etch process may create an opening 402 in the dielectric layer 301 that is self-aligned to the gate spacers 251 formed at the sidewalls of the shared gate structure 231 and the gate cap 241. In one embodiment, a bottom surface of the opening 402 may be below a level of top surfaces of the first and the second S/D region 211 and 212 of the first and the second transistor 201 and 202.

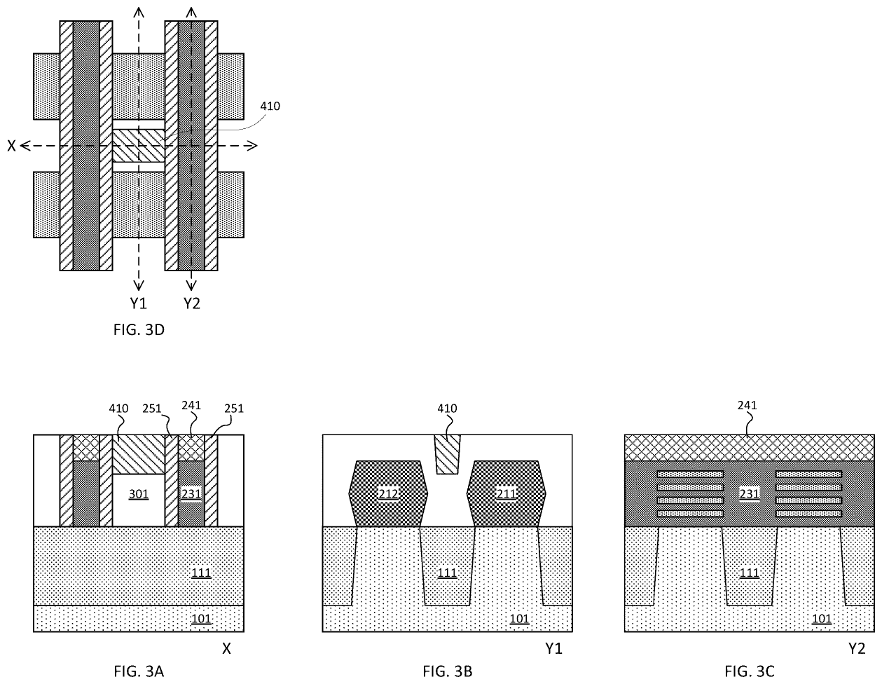

FIGS. 3A, 3B, and 3C are demonstrative illustrations of different cross-sectional views and FIG. 3D is a simplified top view of a semiconductor structure in a step of manufacturing thereof according to one embodiment of present invention. More particularly, following the step illustrated in FIGS. 2A-2D, embodiments of present invention provide filling the opening 402 with a dielectric material, such as silicon-nitride (SiN), silicon-carbide (SiC), silicon-oxy-carbide (SiOC), and the filling may be made through a deposition process such as, for example, an atomic layer deposition (ALD) process, a chemical vapor deposition (CVD) process, or a physical vapor deposition (PVD) process. After the deposition, a chemical mechanical polishing (CMP) process may be applied to remove any excess dielectric material that were deposited on top of the gate spacers 251 and gate cap 241 of the first and the second transistor 201 and 202, thereby creating a dielectric contact cut 410 that is planarized to have a top surface that is coplanar with a top surface of the gate cap 241. In one embodiment, a bottom surface of the dielectric contact cut 410 may be below a level of the top surfaces of the first and the second S/D region 211 and 212 of the first and the second transistor 201 and 202. In other words, the dielectric contact cut 410 may have a depth that extends below the top surfaces of the first and the second S/D region 211 and 212 of the first and the second transistor 201 and 202.

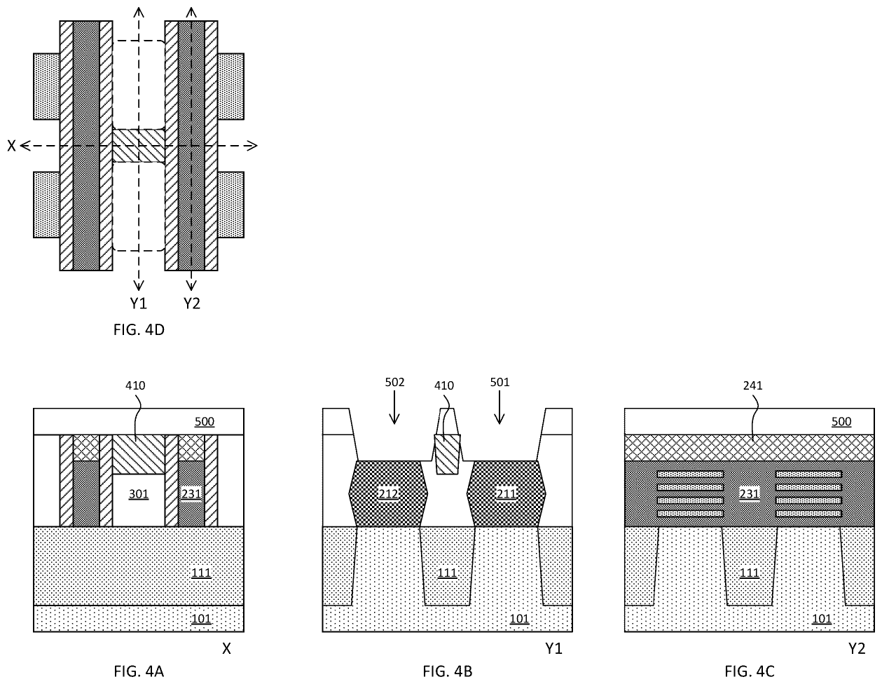

FIGS. 4A, 4B, and 4C are demonstrative illustrations of different cross-sectional views and FIG. 4D is a simplified top view of a semiconductor structure in a step of manufacturing thereof according to one embodiment of present invention. More particularly, following the step illustrated in FIGS. 3A-3D, embodiments of present invention provide, optionally, forming another dielectric layer 500 through, for example, a deposition process on top of the dielectric layer 301 and the dielectric contact cut 410 embedded in the dielectric layer 301. The dielectric layer 500 may be on top of the gate cap 241 and gate spacers 251 of the first and the second transistor 201 and 202 as well. Next, one or more contact openings may be created to expose the first and the second S/D region 211 and 212 of the first and the second transistor 201 and 202. For example, a first and a second contact opening 501 and 502 may be created in the dielectric layer 301, through the dielectric layer 500, to expose top surfaces of the first and the second S/D region 211 and 212 of the first and the second transistor 201 and 202.

In one embodiment, the first and the second contact opening 501 and 502 may be created by first forming a hard mask, or soft mask, on top of the dielectric layer 500 having a pattern of openings corresponding to the first and the second contact opening 501 and 502. Subsequently an etch process may be applied to etch the dielectric layer 500 and the underneath dielectric layer 301, thereby creating the first and the second contact opening 501 and 502. The etch process may be a process that is selective to both the dielectric contact cut 410 and the gate spacers 251 and gate cap 241.

In another embodiment, the first and the second contact opening 501 and 502 may be created by first forming a hard mask, or soft mask, on top of the dielectric layer 500. The hard mask, or soft mask, may have a single opening that expands across a region that covers both the first and the second S/D region 211 and 212. An etch process may then be applied to etch the dielectric layer 500 through the single opening. The etch process may be selective to the dielectric contact cut 410 thereby may result in creating the first contact opening 501 and the second contact opening 502 that, at one side thereof, are self-aligned to the dielectric contact cut 410.

In yet another embodiment, the first and the second contact opening 501 and 502 may be directly created in the dielectric layer 301, without the use of the dielectric layer 500, using the hard mask or soft mask and selective etch process as described above. Other embodiments may be used as well.

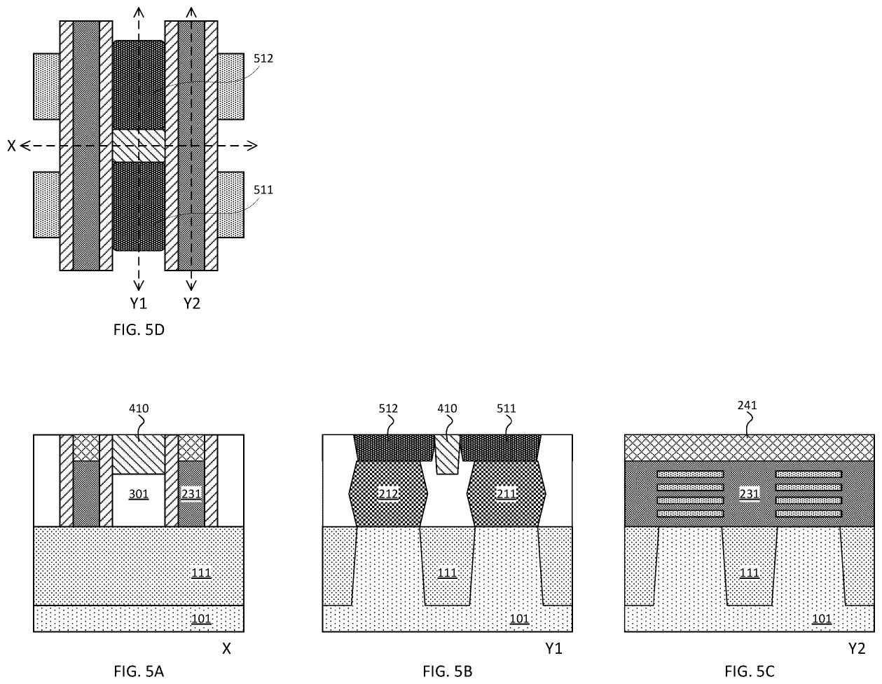

FIGS. 5A, 5B, and 5C are demonstrative illustrations of different cross-sectional views and FIG. 5D is a simplified top view of a semiconductor structure in a step of manufacturing thereof according to one embodiment of present invention. More particularly, following the step illustrated in FIGS. 4A-4D, embodiments of present invention provide filling the first and the second contact opening 501 and 502 with a conductive material, such as tungsten (W), copper (Cu), cobalt (Co), ruthenium (Ru), via a silicide liner such as titanium (Ti), nickel (Ni), or nickel-platinum (NiPt) silicide liner and a thin metal adhesion liner such as tantalum-nitride (TaN) or titanium-nitride (TiN), to form a first S/D contact 511 and a second S/D contact 512. A CMP process may subsequently be applied to first remove excess conductive materials and then remove the dielectric layer 500, thereby creating the first S/D contact 511 and the second S/D contact 512. Particularly, the CMP process may remove the dielectric layer 500 until top surfaces of the dielectric contact cut 410 and the gate cap 241 are exposed. In other words, the first and the second S/D contact 511 and 512 may be planarized to have top surfaces that are coplanar with the top surface of the dielectric contact cut 410 and coplanar with the top surface of the gate cap 241.

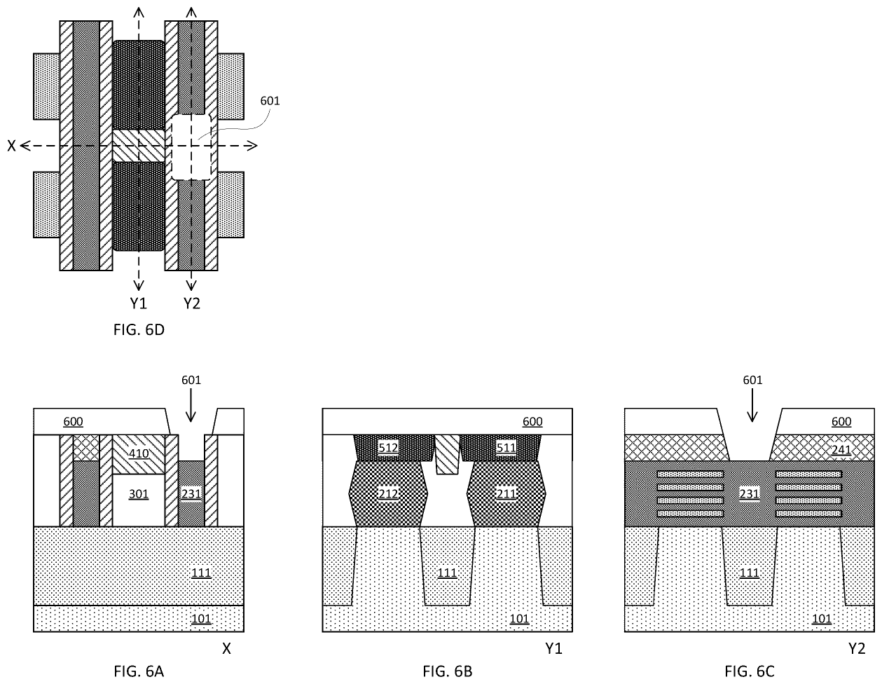

FIGS. 6A, 6B, and 6C are demonstrative illustrations of different cross-sectional views and FIG. 6D is a simplified top view of a semiconductor structure in a step of manufacturing thereof according to one embodiment of present invention. More particularly, following the step illustrated in FIGS. 5A-5D, embodiments of present invention provide forming a dielectric layer 600 on top of the gate cap 241, and creating a gate contact opening 601 in the gate cap 241 through the dielectric layer 600 to expose a portion of the gate structure 231 shared by the first and the second transistor 201 and 202. The creation of the gate contact opening 601 may be made through an etch process selective to the gate spacers 251 such that the opening may be self-aligned to the gate spacers 251.

In one embodiment, the gate contact opening 601 may be created in a position vertically above the gate structure 231 and horizontally in an extension of the dielectric contact cut 410. The extension may be in a direction along a length of the gate structure 231. In other words, Direction of the extension is along a length (and thus perpendicular to a width) of the first and the second gate (or the gate structure 231) of the first and the second transistor 201 and 202.

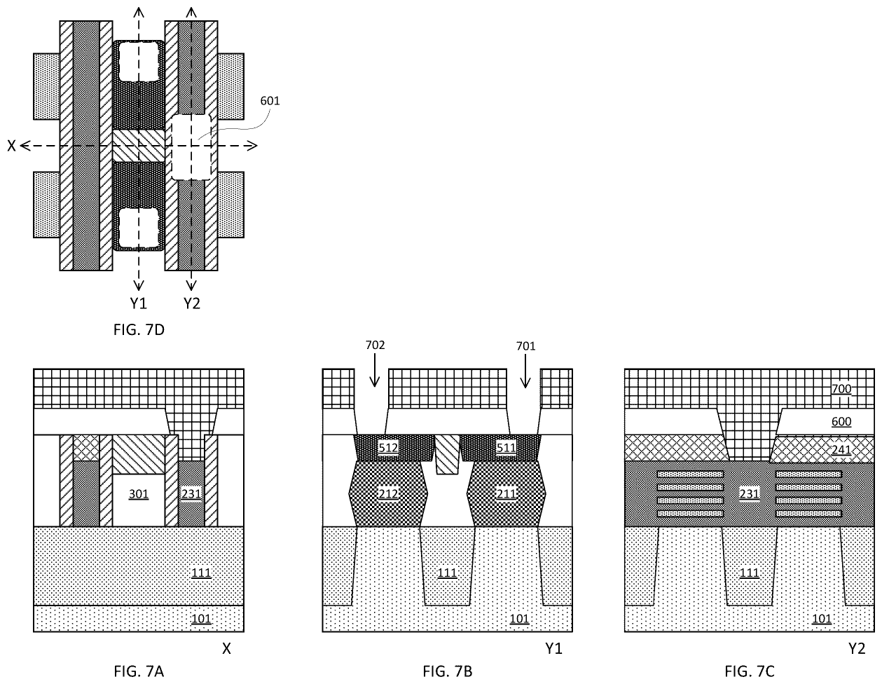

FIGS. 7A, 7B, and 7C are demonstrative illustrations of different cross-sectional views and FIG. 7D is a simplified top view of a semiconductor structure in a step of manufacturing thereof according to one embodiment of present invention. More particularly, following the step illustrated in FIGS. 6A-6D, embodiments of present invention provide forming another mask layer (hard mask such as SiN, SiO₂, etc. or soft mask such as an organic planarization layer etc.) on top of the dielectric layer 600. The mask layer may fill the gate contact opening 601 thereby protecting the gate contact opening 601 from subsequent processing steps.

Next, embodiments of present invention provide patterning the mask layer into a mask 700, for example through a lithographic patterning and etch process. The mask 700 may be created to have, for example, a first via opening 701 and a second via opening 702. The first and the second via opening 701 and 702 may respectively expose a portion of the top surfaces of the first and the second S/D contact 511 and 512 respectively.

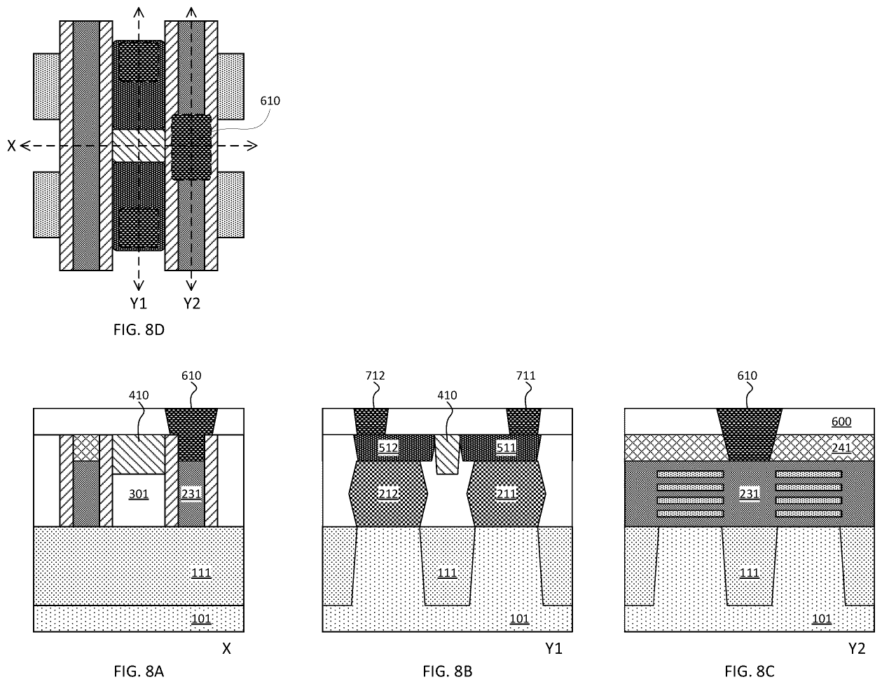

FIGS. 8A, 8B, and 8C are demonstrative illustrations of different cross-sectional views and FIG. 8D is a simplified top view of a semiconductor structure in a step of manufacturing thereof according to one embodiment of present invention. More particularly, following the step illustrated in FIGS. 7A-7D, embodiments of present invention provide selectively removing the mask 700 on top of the dielectric layer 600. The removal of the mask 700 may include removing material of the mask layer in the gate contact opening 601 in the dielectric layer 600 and the gate cap 241 thereby re-creating the opening 601 and exposing the portion of the gate structure 231 shared by the first and the second transistor 201 and 202.

Embodiments of present invention may further provide filling the gate contact opening 601 and the first and the second via opening 701 and 702 with a conductive material such as, for example, ruthenium (Ru), cobalt (Co), tungsten (W), copper (Cu), etc. and optionally with a thin metal adhesion layer such as tantalum-nitride (TaN) or titanium-nitride (TiN), to form a gate contact 610, a first via contact 711 contacting the first S/D contact 511, and a second via contact 712 contacting the second S/D contact 512. The conductive material of the gate contact 610 and the first and the second via contact 711 and 712 may be deposited through an ALD process, a CVD process or a PVD process. After the deposition, a CMP process may be applied to remove any excess conductive material on top of the dielectric layer 600.

In one embodiment, the gate contact 610 may be formed or positioned along an extension of the dielectric contact cut 410. The extension of the dielectric contact cut 410 may be along a direction following the direction of the length of the gate structure 231, that is, the direction of the first and the second gate of the first and the second transistor 201 and 202. The gate contact 610, more particularly a lower portion of the gate contact 610 may be separated from the dielectric contact cut 410 by the gate spacer 251. The gate contact 610 may have a top surface that is coplanar with a top surface of the dielectric layer 600. In other words, the top surface of the gate contact 610 may be above a top surface of the dielectric contact cut 410, which is coplanar with a top surface of the gate cap 241. On the other hand, the top surface of the gate contact 610 may be coplanar with top surfaces of the first and the second via contact 711 and 712, which respectively contact the first and the second S/D contact 511 and 512, which in-turn contact the first and the second S/D region 211 and 212 of the first and the second transistor 201 and 202.

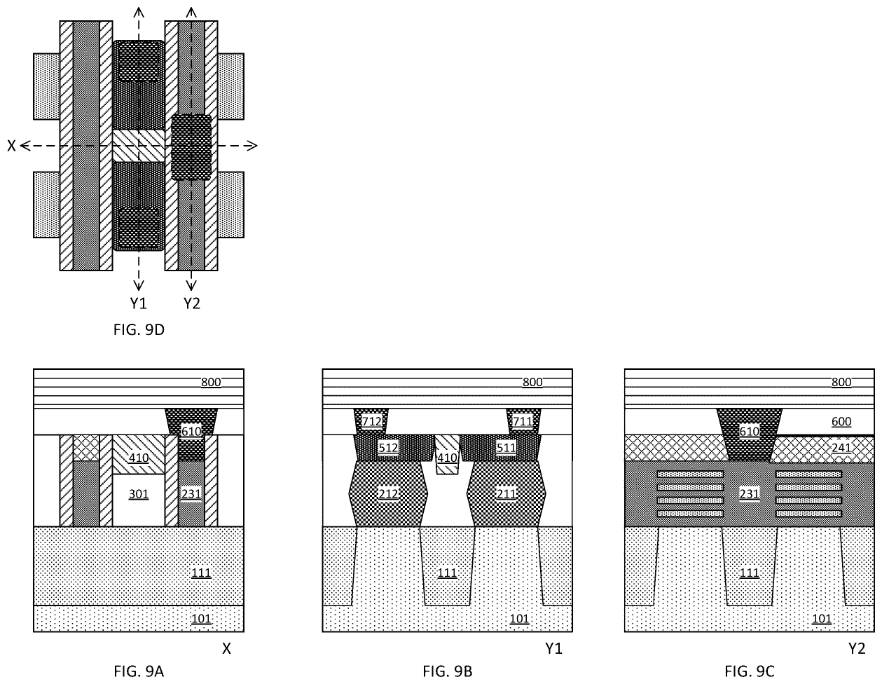

FIGS. 9A, 9B, and 9C are demonstrative illustrations of different cross-sectional views and FIG. 9D is a simplified top view of a semiconductor structure in a step of manufacturing thereof according to one embodiment of present invention. More particularly, following the step illustrated in FIGS. 8A-8D, embodiments of present invention provide forming or building a back-end-of-line (BEOL) structure 800 on top of the dielectric layer 600 to be in contact with the gate contact 610, and the first and the second via contact 711 and 712. The BEOL structure 800 may include one or more metal lines of one or more metal levels and may provide powering and/or signal routing functionalities to the first and the second transistor 201 and 202.

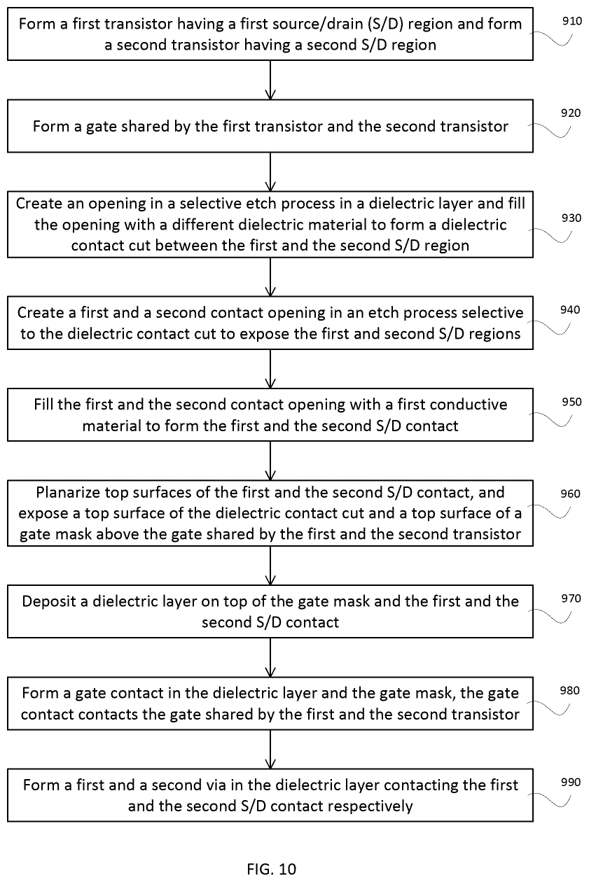

FIG. 10 is a demonstrative illustration of a flow-chart of a method of manufacturing a semiconductor structure according to embodiments of present invention. The method includes (910) form a first transistor having a first source/drain (S/D) region and forming a second transistor having a second S/D region; (920) forming a gate structure shared by the first transistor and the second transistor, the gate structure includes a first gate of the first transistor and a second gate of the second transistor; (930) creating an opening in a selective etch process in a dielectric layer and subsequently filling the opening with a different dielectric material to form a dielectric contact cut between the first and the second S/D region; (940) creating a first and a second contact opening in an etch process selective to the dielectric contact cut to expose the first and the second S/D region; (950) filling the first and the second contact opening with a first conductive material to form the first and the second S/D contact; (960) planarizing top surfaces of the first and the second S/D contact, and exposing a top surface of the dielectric contact cut and a top surface of a gate cap above the gate structure shared by the first and the second transistor; (970) depositing a dielectric layer on top of the gate cap and the first and the second S/D contact; (980) forming a gate contact in the dielectric layer and the gate cap, where the gate contact contacts the gate structure shared by the first and the second transistor; and (990) forming a first and a second via in the dielectric layer that contact the first and the second S/D contact respectively.

Various examples may possibly be described by one or more of the following features in the following numbered clauses:

Clause 1: A semiconductor structure comprising: a dielectric contact cut between a first source/drain (S/D) contact of a first transistor and a second S/D contact of a second transistor; and a dielectric gate cap on top of a gate structure, the first transistor and the second transistor sharing the gate structure, wherein a top surface of the dielectric contact cut is substantially coplanar with a top surface of the dielectric gate cap.

Clause 2: The semiconductor structure of clause 1, further comprising a gate contact that is in contact with the gate structure shared by the first and the second transistor, wherein a lower portion of the gate contact is separated from the dielectric contact cut by a gate spacer.

Clause 3: The semiconductor structure of clause 2, further comprising a first via in contact with the first S/D contact and a second via in contact with the second S/D contact, wherein top surfaces of the first via and the second via are coplanar with a top surface of the gate contact.

Clause 4: The semiconductor structure of clause 1, wherein the gate contact is positioned in an extension of the dielectric contact cut, the extension being in a direction along a length of the gate structure shared by the first and the second transistor.

Clause 5: The semiconductor structure of clause 1, wherein a top surface of the gate contact is above the top surface of the dielectric contact cut.

Clause 6: The semiconductor structure of clause 1, wherein the top surface of the dielectric contact cut is substantially coplanar with top surfaces of the first and the second S/D contact of the first and the second transistor.

Clause 7: The semiconductor structure of clause 1, wherein the dielectric contact cut is horizontally between a first S/D region underneath the first S/D contact of the first transistor and a second S/D region underneath the second S/D contact of the second transistor.

Clause 8: The semiconductor structure of clause 1, wherein the dielectric contact cut has a depth that is below a top surface of a first S/D region of the first transistor and below a top surface of a second S/D region of the second transistor.

Clause 9: A method of forming a semiconductor structure comprising: forming a first transistor having a first source/drain (S/D) region; forming a second transistor having a second S/D region; forming a gate structure shared by the first transistor and the second transistor; forming a dielectric contact cut and a first and a second S/D contact separated by the dielectric contact cut, the first and the second S/D contact contacting, respectively, the first and the second S/D region of the first and the second transistor; and forming a gate contact contacting the gate structure shared by the first and the second transistor, wherein a lower portion of the gate contact being horizontally separated from the dielectric contact cut by a gate spacer, and a top surface of the gate contact being above a top surface of the dielectric contact cut.

Clause 10: The method of clause 9, wherein forming the dielectric contact cut comprises creating an opening, in an etch process selective to the gate spacer, in a dielectric layer between the first and the second S/D region and subsequently filling the opening with a first dielectric material to form the dielectric contact cut.

Clause 11: The method of clause 10, wherein forming the first and the second S/D contact comprises: creating a first and a second contact opening, in an etch process selective to the dielectric contact cut, in the dielectric layer with the first and the second contact opening exposing the first and the second S/D region; filling the first and the second contact opening with a first conductive material; and applying a chemical-mechanical-polishing (CMP) process to planarize top surfaces of the first and the second S/D contact, wherein the CMP process exposes a top surface of the dielectric contact cut and a top surface of a gate cap above the gate structure shared by the first and the second transistor.

Clause 12: The method of clause 11, wherein forming the gate contact comprises: creating a gate contact opening, in an etch process selective to the gate spacer, in the gate cap exposing a portion of the gate structure shared by the first and the second transistor; and filling the gate contact opening with a second conductive material to form the gate contact.

Clause 13: The method of clause 12, further comprising: depositing a dielectric layer on top of the gate cap and the first and the second S/D contact; and forming in the dielectric layer one or more vias contacting the first and the second S/D contact.

Clause 14: The method of clause 9, wherein the gate contact is positioned in an extension of the dielectric contact cut, the extension being in a direction along a length of the gate structure shared by the first and the second transistor.

Clause 15: The method of clause 9, wherein the dielectric contact cut extends below top surfaces of the first S/D region and the second S/D region of the first and the second transistor.

Clause 16: A semiconductor structure comprising: a dielectric contact cut between a first source/drain (S/D) contact of a first transistor and a second S/D contact of a second transistor; a gate structure shared by the first and the second transistor; and a gate cap on top of the gate structure, wherein a top surface of the dielectric contact cut is substantially coplanar with a top surface of the gate cap and substantially coplanar with top surfaces of the first S/D contact and the second S/D contact.

Clause 17: The semiconductor structure of clause 16, further comprising a gate contact in contact with the gate structure shared by the first and the second transistor, wherein the gate structure includes a first gate of the first transistor and a second gate of the second transistor, and wherein the gate contact is insulated from the dielectric contact cut by a gate spacer.

Clause 18: The semiconductor structure of clause 17, wherein the gate contact is formed in a position at an extension of the dielectric contact cut, the extension being in a direction along a length of the gate structure shared by the first and the second transistor.

Clause 19: The semiconductor structure of clause 18, wherein a top surface of the gate contact is above the top surface of the dielectric contact cut.

Clause 20: The semiconductor structure of clause 16, wherein the dielectric contact cut has a depth that is below a top surface of a first S/D region of the first transistor and below a top surface of a second S/D region of the second transistor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a dielectric contact cut between a first source/drain (S/D) contact of a first transistor and a second S/D contact of a second transistor; and
a dielectric gate cap on top of a gate structure, the first transistor and the second transistor sharing the gate structure,
wherein a top surface of the dielectric contact cut is substantially coplanar with a top surface of the dielectric gate cap.

2. The semiconductor structure of claim 1, further comprising a gate contact that is in contact with the gate structure shared by the first and the second transistor, wherein a lower portion of the gate contact is separated from the dielectric contact cut by a gate spacer.

3. The semiconductor structure of claim 2, further comprising a first via in contact with the first S/D contact and a second via in contact with the second S/D contact, wherein top surfaces of the first via and the second via are coplanar with a top surface of the gate contact.

4. The semiconductor structure of claim 1, wherein the gate contact is positioned in an extension of the dielectric contact cut, the extension being in a direction along a length of the gate structure shared by the first and the second transistor.

5. The semiconductor structure of claim 1, wherein a top surface of the gate contact is above the top surface of the dielectric contact cut.

6. The semiconductor structure of claim 1, wherein the top surface of the dielectric contact cut is substantially coplanar with top surfaces of the first and the second S/D contact of the first and the second transistor.

7. The semiconductor structure of claim 1, wherein the dielectric contact cut is horizontally between a first S/D region underneath the first S/D contact of the first transistor and a second S/D region underneath the second S/D contact of the second transistor.

8. The semiconductor structure of claim 1, wherein the dielectric contact cut has a depth that is below a top surface of a first S/D region of the first transistor and below a top surface of a second S/D region of the second transistor.

9. A method of forming a semiconductor structure comprising:
forming a first transistor having a first source/drain (S/D) region;
forming a second transistor having a second S/D region;
forming a gate structure shared by the first transistor and the second transistor;
forming a dielectric contact cut and a first and a second S/D contact separated by the dielectric contact cut, the first and the second S/D contact contacting, respectively, the first and the second S/D region of the first and the second transistor; and
forming a gate contact contacting the gate structure shared by the first and the second transistor,
wherein a lower portion of the gate contact being horizontally separated from the dielectric contact cut by a gate spacer, and a top surface of the gate contact being above a top surface of the dielectric contact cut.

10. The method of claim 9, wherein forming the dielectric contact cut comprises creating an opening, in an etch process selective to the gate spacer, in a dielectric layer between the first and the second S/D region and subsequently filling the opening with a first dielectric material to form the dielectric contact cut.

11. The method of claim 10, wherein forming the first and the second S/D contact comprises:
creating a first and a second contact opening, in an etch process selective to the dielectric contact cut, in the dielectric layer with the first and the second contact opening exposing the first and the second S/D region;
filling the first and the second contact opening with a first conductive material; and
applying a chemical-mechanical-polishing (CMP) process to planarize top surfaces of the first and the second S/D contact, wherein the CMP process exposes a top surface of the dielectric contact cut and a top surface of a gate cap above the gate structure shared by the first and the second transistor.

12. The method of claim 11, wherein forming the gate contact comprises:
creating a gate contact opening, in an etch process selective to the gate spacer, in the gate cap exposing a portion of the gate structure shared by the first and the second transistor; and
filling the gate contact opening with a second conductive material to form the gate contact.

13. The method of claim 12, further comprising:
depositing a dielectric layer on top of the gate cap and the first and the second S/D contact; and
forming in the dielectric layer one or more vias contacting the first and the second S/D contact.

14. The method of claim 9, wherein the gate contact is positioned in an extension of the dielectric contact cut, the extension being in a direction along a length of the gate structure shared by the first and the second transistor.

15. The method of claim 9, wherein the dielectric contact cut extends below top surfaces of the first S/D region and the second S/D region of the first and the second transistor.

16. A semiconductor structure comprising:
a dielectric contact cut between a first source/drain (S/D) contact of a first transistor and a second S/D contact of a second transistor;
a gate structure shared by the first and the second transistor; and
a gate cap on top of the gate structure,
wherein a top surface of the dielectric contact cut is substantially coplanar with a top surface of the gate cap and substantially coplanar with top surfaces of the first S/D contact and the second S/D contact.

17. The semiconductor structure of claim 16, further comprising a gate contact in contact with the gate structure shared by the first and the second transistor, wherein the gate structure includes a first gate of the first transistor and a second gate of the second transistor, and wherein the gate contact is insulated from the dielectric contact cut by a gate spacer.

18. The semiconductor structure of claim 17, wherein the gate contact is formed in a position at an extension of the dielectric contact cut, the extension being in a direction along a length of the gate structure shared by the first and the second transistor.

19. The semiconductor structure of claim 18, wherein a top surface of the gate contact is above the top surface of the dielectric contact cut.

20. The semiconductor structure of claim 16, wherein the dielectric contact cut has a depth that is below a top surface of a first S/D region of the first transistor and below a top surface of a second S/D region of the second transistor.
